(19) United States
(12) Patent Application Publication
(10) Pub. No.: US 2010/0101645 A1
(43) Pub. Date: Apr. 29, 2010

(54) ELECTRODE OF DYE-SENSITIZED SOLAR CELL, MANUFACTURING METHOD THEREOF AND DYE-SENSITIZED SOLAR CELL

(75) Inventors: Hyun-Jun KIM, Suwon-si (KR); Sung-Soo Park, Seongnam-si (KR); Young-Sun Won, Seoul (KR); Ji-Chul An, Goyang-si (KR); Jin-Uk Lee, Suwon-si (KR); Soo-Yeong Ji, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/606,489

(22) Filed: Oct. 27, 2009

(30) Foreign Application Priority Data
Oct. 27, 2008 (KR) 10-2008-0105289

(51) Int. Cl. H01L 31/00; B05D 5/12; C23C 14/34

(52) U.S. Cl. 136/256; 427/74; 204/192.29

(57) ABSTRACT

A dye-sensitized solar cell, an electrode of the dye-sensitized solar cell, a method of manufacturing the electrode of the dye-sensitized solar cell are disclosed. The method of manufacturing the electrode of the dye-sensitized solar cell in accordance with an embodiment of the present invention includes: forming a metal transparent electrode on one surface of a transparent polymer board, in which the metal transparent electrode has holes formed therein; forming a electron transfer layer on the metal transparent electrode; and absorbing photosensitive dye into the electron transfer layer. According to the method as set forth above, a flexible solar cell can be implemented by using a flexible electrode, and another transparent electrode layer using ITO can be omitted by using the nano-patterned metal transparent electrode. Therefore, the highly efficient dye-sensitized solar cell can be implemented by the excellent conductivity of metals and the plasmon effect.

### CROSS-REFERENCE TO RELATED APPLICATIONS

This application claims the benefit of Korean Patent Application No. 10-2008-0105289, filed with the Korean Intellectual Property Office on Oct. 27, 2008, the disclosure of which is incorporated herein by reference in its entirety.

### BACKGROUND

1. Technical Field

The present invention relates to a dye-sensitized solar cell, an electrode of the dye-sensitized solar cell, a method of manufacturing the electrode of the dye-sensitized solar cell.

2. Description of the Related Art

A dye-sensitized solar cell is a relatively new class of low cost solar cell that chemically generates electricity using its ability to create a conduction electron when a dye absorbs sunlight. Because of its advantages, such as low-cost materials, easy production, flexibility, lightweight and transparency, the dye-sensitized solar cell is emerging as one of the next generation solar cell technologies that can replace the silicon solar cell market in the future.

Typically, the dye-sensitized solar cell consists of a electron transport layer, dye, which generates electrons, electrolyte, which supplies electrons, a corresponding electrode, which is, for example, platinum (Pt), and a transparent conductive electrode, on a transparent electrode deposited over a glass board. The electron transport layer is made of an n-type oxide semiconductor, such as TiO₂, ZnO and SnO₂ existing in the form of a porous film, having a wide range of band gaps and a monomolecular layer of dye is adhered to the surface of the electron transport layer.

The operating principle of the dye-sensitized solar cell will be described hereinafter. When incident sunlight strikes the solar cell, an electron in the highest occupied molecular orbital (HOMO) level of the dye absorbs solar energy and becomes excited to the lowest unoccupied molecular orbital (LUMO) level, and then the electron is quickly injected into the conduction band (CB) to form a conduction electron. Here, an empty space, from which the electron has escaped, of the HOMO level of the dye is filled with another electron provided from an ion (I-) in a cathode substance (electrolyte).

While sunlight is incident, the conduction electron is accumulated in the electron transport layer, creating a shortage of electrons in the electrolyte over a period of time. In other words, it can be seen that holes are accumulated and an electromotive force is formed by accumulated carriers

Such a dye-sensitized solar cell can be manufactured in a simple way. That is, a lower electrode board is formed by coating a TiO₂ colloidal solution over a glass board, on which fluorine-doped tin oxide (FTO) or ITO is deposited, and then sintering the glass board at a temperature of about 450 degrees Celsius. The above process is repeated until desired thickness and state of the electron transport layer are obtained. After that, the glass board is dipped in the dye over a very lengthy period of time (about 2 to 3 days) such that the surface of TiO₂ particles is dyed. Meanwhile, an upper electrode board is formed by preparing a glass board, on which a hole for injecting the electrolyte is formed, and coating, for example, platinum (Pt) on the glass board by way of sputtering. Then, the dye-sensitized solar cell is completed by coupling the upper board with the lower board by using a high polymer package material, injecting the electrolyte as the cathode substance into the dye-sensitized solar cell through the pre-fabricated hole and then sealing the hole.

Such a dye-sensitized solar cell described above can be manufactured with as low as 25% of the manufacturing cost of a conventional silicon solar cell due to its low-cost materials and easy production, and can be implemented in various applications because it is light, thin and transparent and can realize various colors. Moreover, the dye-sensitized solar cell has its own flexibility, and thus a flexible solar cell can be implemented if an appropriate flexible transparent electrode is used.

Particularly, the solar cell for mobile devices is a mobile power source and thus is required to be light and flexible. Since the dye-sensitized solar cell has its own flexibility, a flexible solar cell can be implemented if an appropriate flexible transparent electrode is implemented.

However, the conventional dye-sensitized solar cell manufacturing technologies require a high temperature sintering process, making it difficult to use a flexible board, such as plastic, and a transparent electrode, such as conductive polymer. Therefore, an oxide transparent electrode, for example, indium tin oxide (ITO) on a glass board, is currently used for the most dye-sensitized solar cells.

Recently, a new electron transport layer that can be sintered at a low temperature of about 120 degrees Celsius has been developed to allow for use of a commercial conductive plastic board. In this case, however, it has been inevitable that the solar conversion efficiency is sacrificed. Moreover, compared with the ITO board, it can be expected that the transparent upper electrode board has lower efficiency due to its lower transparency and lower conductivity. As a result, there have been practical difficulties in implementing a high-efficiency flexible dye-sensitized solar cell.

### SUMMARY

The present invention provides a method of manufacturing a highly efficient flexible solar cell by using an electrode of a dye-sensitized solar cell including a metal transparent electrode.

An aspect of the present invention provides a method of manufacturing an electrode of a dye-sensitized solar cell. The method in accordance with an embodiment of the present invention includes: forming a metal transparent electrode on one surface of a transparent polymer board, in which the metal transparent electrode has holes formed therein; forming a electron transfer layer on the metal transparent electrode; and absorbing photosensitive dye into the electron transfer layer.

The transparent polymer board can be a flexible board and made of a thermoplastic or photocurable material.

The forming of the metal transparent electrode can include: forming an intaglio nano-pattern on one surface of the transparent polymer board; and filling a conductive metal in the intaglio nano-pattern.

The forming of the intaglio nano-pattern can include: preparing a stamp, in which a relievo nano-pattern corresponding to the intaglio nano-pattern is formed; pressing and hardening the stamp by facing the surface of the stamp in which the relievo nano-pattern is formed against one surface of the transparent polymer board; and exposing the intaglio nano-pattern by separating the stamp. Moreover, the filling of the conductive metal can be performed by way of sputtering.

The holes are formed on the metal transparent electrode at regular intervals, in which the holes are smaller in size than the wavelength of visible light.

The forming of the electron transfer layer can include: coating nano-crystal oxide on the metal transparent electrode; and annealing the nano-crystal oxide. Here, the nano-crystal oxide can include TiO₂.

Another aspect of the present invention provides an electrode of a dye-sensitized solar cell. The electrode in accordance with an embodiment of the present invention include: a transparent polymer board; a metal transparent electrode, which is formed on one surface of the transparent polymer board and in which the metal transparent electrode has holes formed therein; and a electron transfer layer, which is formed on one surface of the transparent polymer board and in which the electron transfer layer has photosensitive dye absorbed therein.

The transparent polymer board can be a flexible board, and the metal transparent electrode can buried in the transparent polymer board. The holes can be formed on the metal transparent electrode at regular intervals, in which the holes are smaller than the wavelength of visible light in size. The electron transfer layer can be made of a material comprising TiO₂.

Yet another aspect of the present invention provides a dye-sensitized solar cell. The dye-sensitized solar cell in accordance with an embodiment of the present invention includes: a lower electrode, including a transparent polymer board and a electron transfer layer, in which a metal transparent electrode is formed on one surface of the transparent polymer board, the metal transparent electrode has holes formed therein, and the electron transfer layer is formed on one surface of the transparent polymer substance and has photosensitive dye absorbed therein; an upper electrode, which includes an upper electrode board and a metal film and in which the metal film is formed on one surface of the upper electrode board; and an electrolyte, which is interposed between the lower electrode and the upper electrode.

Here, the metal transparent electrode can be buried in the transparent polymer board. The holes can be formed on the metal transparent electrode at regular intervals, in which the holes are smaller than the wavelength of visible light in size. The electron transfer layer can be made of a material comprising TiO₂.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing an electrode in a dye-sensitized solar cell in accordance with an aspect of the present invention.

FIGS. 2 to 7 show the process flow of an embodiment of the method of manufacturing an electrode in a dye-sensitized solar cell in accordance with an aspect of the present invention.

FIG. 8 is a perspective view illustrating a metal transparent electrode formed by the method of manufacturing an electrode in a dye-sensitized solar cell in accordance with an aspect of the present invention.

FIG. 9 is a graph illustrating an optical transmittance spectrum in a dye-sensitized solar cell in accordance with another aspect of the present invention.

FIG. 10 is a cross-sectional view illustrating an embodiment of a dye-sensitized solar cell in accordance with another aspect of the present invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed descriptions of related art are omitted when it is deemed that they may unnecessarily obscure the essence of the invention.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

A dye-sensitized solar cell, an electrode of the dye-sensitized solar cell, a method of manufacturing the electrode according to certain embodiments of the present invention will be described below in more detail with reference to the accompanying drawings. Those components that are the same or are in correspondence are rendered the same reference numeral regardless of the figure number, and redundant descriptions are omitted.

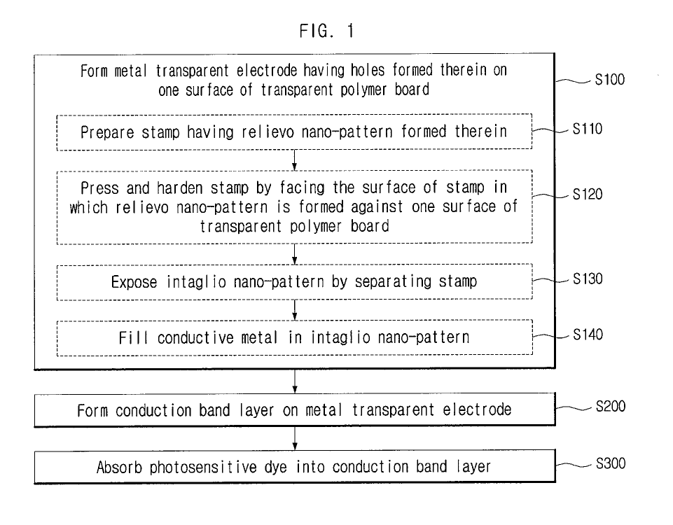

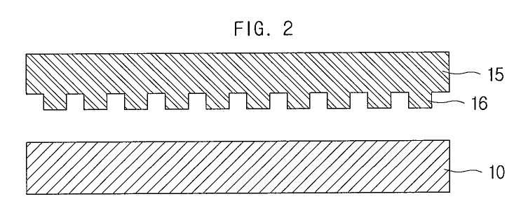

FIG. 1 is a flowchart illustrating a method of manufacturing an electrode in a dye-sensitized solar cell in accordance with an aspect of the present invention, and FIGS. 2 to 7 are the process flow of an embodiment of the method of manufacturing an electrode in a dye-sensitized solar cell in accordance with an aspect of the present invention. Illustrated in FIGS. 2 to 7 are a transparent polymer board 10, a stamp 15, a relievo nano-pattern 16, a metal transparent electrode 20, a electron transfer layer 30 and photosensitive dye 35.

First, the metal transparent electrode 20 having a hole formed therein is formed on one surface of the transparent polymer board 10 (S100).

The transparent polymer board 10 is a base of an electrode, on which the electron transfer layer 30 is formed, and can be made of a transparent material through which light can penetrate. Particularly, a flexible material that does not get damaged through repeated folding can be used to implement a flexible dye-sensitized solar cell.

Examples of such flexible material can include polyethylene terephthalate (PET), polyethylene naphthalate (PEN), polyimides, polymeric hydrocarbons, celluloses, plastic, polycarbonate and polystyrene.

The metal transparent electrode 20 is an electrode that is designed in such a way that it has conductivity and optical transmittance allowing light to pass through, and a highly conductive metal such as silver or copper is used for the metal transparent electrode 20 having nanometer-sized holes formed therein. Despite the high conductivity, metals such as silver and copper are known to be not suitable for the metal transparent electrode due to its low transmittance although they are manufactured as a thin film. Even if these metals are made in a mesh or grid type to raise their optical transmittance, the magnitude of sheet resistance is increased when the materials are formed with an opening that is greater than the optical wavelength in order to obtain the optical transmittance.

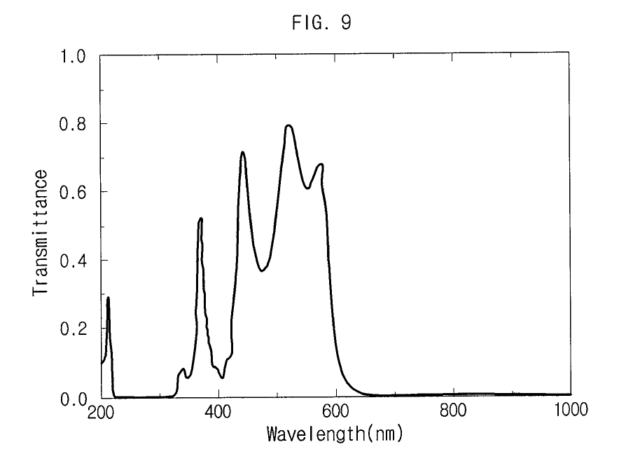

However, recent studies have shown that a high optical transmittance can be obtained even at an optically opaque thickness of 200˜300 nm if nanometer-sized holes are formed at regular intervals on a metal thin film. The result contradicts what has been generally believed that a hole that is smaller than the optical wavelength can not allow light to pass through. FIG. 9 shows an optical transmittance spectrum of a metal film with a thickness of 250 nm, on which holes with a diameter of 100 nm are formed at regular intervals of 200 nm in a configuration of rectangular lattice. As described above, a high optical transmittance is observed in a relatively broad region of visible light wavelength band (400 nm to 600 nm). Since the optical transmittance is mainly dependent on the properties and structure of the material, a metal transparent electrode 20 with the optimum efficiency of optical transmittance in a desired range of wavelength bands can be realized through an appropriate design.

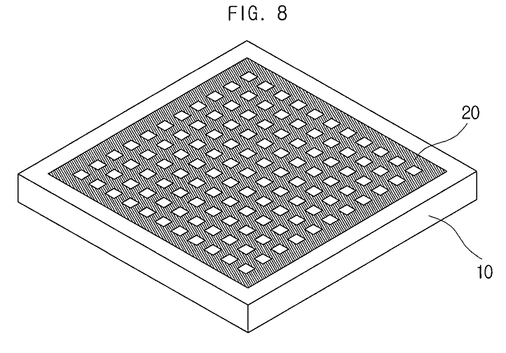

FIG. 8, which is a perspective view illustrating the metal transparent electrode 20 formed by the method of manufacturing an electrode of a dye-sensitized solar cell in accordance with an aspect of the present invention, shows that the metal transparent electrode 20, in which nanometer-sized holes are formed, is formed on the transparent polymer board 10. Through the holes of the metal transparent electrode 20, the transparent polymer board 10 can be partially exposed, and light can pass through the holes. The holes are nanometers in size, which can be smaller than the wavelength of visible light. That is, since the wavelength of visible light is ranged between about 400 nm and 700 nm, the holes can be smaller than 400 nm in size, for example, between 100 nm and 300 nm. When holes of 100 nm to 300 nm in size are formed, they may appear visibly opaque but have an excellent optical transmittance in the visible light wavelength band, allowing light to travel through, as illustrated in FIG. 9.

The present invention utilizes the above property. By designing a nanometer-level regular pattern, not only can a metal thin film with a considerable thickness have an appropriate optical transmittance, but the sheet resistance required for an electrode can be easily obtained by utilizing the excellent conductivity of a metal material. Not only does such designing make it easy to implement a transparent electrode that is made of an inexpensive metal material, but it can also implement a high-quality flexible transparent electrode by using a plastic board.

In the case of the metal transparent electrode 20 implemented through the nanometer-sized patterning, the low energy conversion efficiency of the conventional dye-sensitized solar cell, which has to anneal a electron transfer at low temperatures for the implementation of a flexible solar cell, can be solved. In other words, unlike the conventional structure, in which a ray of sunlight strikes and passes through a transparent electrode at a right angle, the nano-patterned metal transparent electrode 20 allows a ray of incident light to be first coupled to surface plasmons at the boundary of two materials, i.e., the electron transfer layer 30 and the nano-patterned metal, and then propagates the incident light horizontally along the surface of the metal until it decays, increasing the length of time for an interaction between the incident light and the dye formed on the surface of the electron transfer layer 30 (surface plasmon effect). Therefore, the energy conversion efficiency can be improved by increasing the absorption of light by the dye.

Below, a method of forming the metal transparent electrode 20 having the properties described above will be described in detail.

To form the metal transparent electrode 20, a metal layer can be formed on the transparent polymer board 10 having no conductivity by way of electroless plating, such as a sputtering method. In the convention sputtering method, however, it is difficult to form the metal transparent electrode 20, in which nanometer-sized holes are formed at regular intervals, and thus the metal transparent electrode 20, in which regular-sized holes are formed, can be formed by forming a intaglio nano-pattern on one surface of the transparent polymer board 10 and filling the intaglio nano-pattern with a conductive metal. That is, the intaglio nano-pattern becomes a mold for forming the metal transparent electrode 20.

The intaglio nano-pattern can be formed on the transparent polymer board 10 by using a laser. In order to produce the board 10 more easily and repeatedly, however, the stamp, in which the relievo nano-pattern 16 is formed, corresponding to the intaglio nano-pattern can be used.

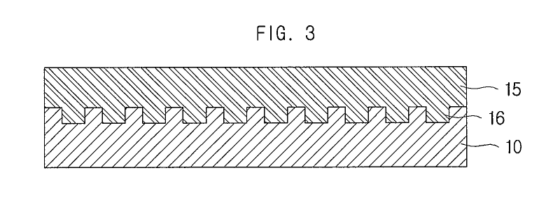

First, the stamp 15, in which the relievo nano-pattern 16 is formed, is prepared, as illustrated in FIGS. 2 and 3 (S110). Then, the stamp 15 is pressed and hardened by facing one surface of the transparent polymer board 10 against the surface in which the relievo nano-pattern 16 is formed (S120). Here, the intaglio nano-pattern can be easily transcribed by using the stamp 15 if the transparent polymer board 10 is made of a thermoplastic or photocurable material. Although the stamp 15 made of a material such as quartz or silicon is described herein, it shall be apparent that any durable material that can easily form the relievo nano-pattern 16 can be used in the present embodiment.

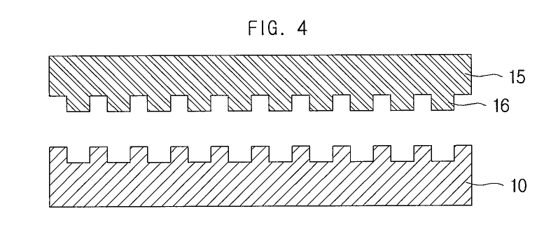

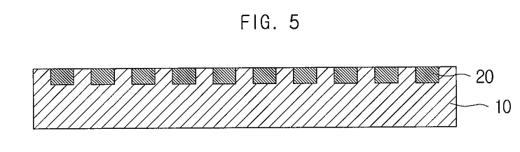

Next, the intaglio nano-pattern is exposed by separating the stamp 15, as illustrated in FIGS. 4 and 5 (S130), and then the intaglio nano-pattern is filled with the conductive metal (S140). A highly conductive metal, such as gold, silver or copper, can be used as the conductive metal. If the conductive metal is coated over the intaglio nano-pattern formed in the transparent polymer board 10 through the sputtering, the metal transparent electrode 20 can be formed as the conductive metal fills the intaglio nano-pattern. A part of the transparent polymer board 10 can be filled in the hole of the metal transparent electrode 20, as illustrated in FIG. 5.

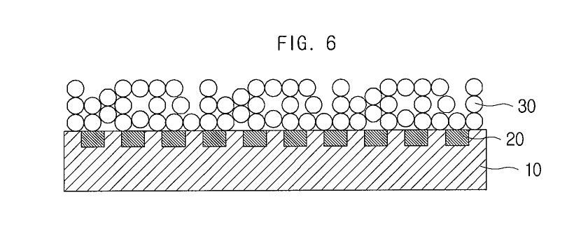

Next, the electron transfer layer 30 is formed on the metal transparent electrode 20, as illustrated in FIG. 6 (S200). The electron transfer layer 30 converts solar energy to electrical energy by coupling the photosensitive dye 35 to its surface, absorbing the solar energy and activating electrons.

Therefore, in order to provide a high quality solar cell electrode, the electron transfer layer 30 has to be made of a material that can easily absorb the photosensitive dye 35 into its surface, and the surface area of the electron transfer layer 30 has to be large so that the total contact area to which the dye is coupled can be wide enough. As a result, the electron transfer layer 30 can be made of nano-crystal oxide. In other words, the electron transfer layer 30 can be formed by coating the nano-crystal oxide on the metal transparent electrode 20 and annealing the nano-crystal oxide. The coating and annealing of the nano-crystal oxide can be repeated until the electron transfer layer 30 reaches a desired thickness.

TiO₂ is most commonly used as the nano-crystal oxide and occurs in nature as the well-known naturally occurring mineral of anatase, rutile and brookite. The anatase, one of the mineral forms of TiO₂, is always found as compact crystals in a spherical shape with a diameter of 20 nm, and thus the anatase generates more photoelectric currents due to its wider surface area. In order to form the electron transfer layer 30 consisting of the anatase form of TiO₂, TiO₂ is coated and then treated through an annealing process at a high temperature (about 450 degrees Celsius). Nevertheless, the electron transfer layer 30 consisting of the anatase form of TiO₂ cannot be formed on the transparent polymer board 10 because a flexible polymer can be damaged by the heat during the annealing process.

On the other hand, the rutile form of TiO₂ is stable at a low temperature and can be thus manufactured at room temperature by the hydrolytic method. The rutile form of TiO₂ has a tetragonal unit cell, which is a rectangular prism with a diameter of 20 nm and a length of 80 nm, and generates less photoelectric currents than the anatase form of TiO₂ due to its smaller surface area. However, when the metal transparent electrode 20, in which nanometer-sized holes are formed, is used, light can be effectively coupled to the electrode due to the surface plasmon effect, as described above. Therefore, even if the rutile form of TiO₂ with the smaller surface area is used, a highly efficient photosensitive solar cell can be provided.

Next, the photosensitive dye 35 is coupled to the electron transfer layer 30 (S300). As described above, the electron transfer layer 30 is made of nano-crystal oxide, allowing the photosensitive dye to couple to its surface. The photosensitive dye 35 functions to separate electric charges and is sensitive to light. Some examples of the photosensitive dye 35 include ruthenium-based organic metallic compounds, organic compounds and quantum-dot inorganic compounds, for example, InP and CdSe. Moreover, a dye molecule generates electron holes when light is irradiated.

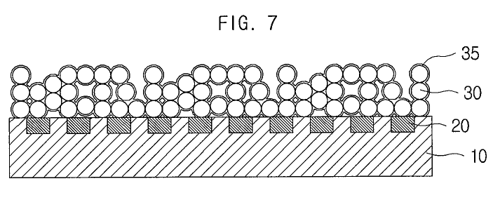

The electrode of the dye-sensitized solar cell formed through the processes described above, which is illustrated in FIG. 7, functions as an electrode that absorbs sunlight and converts the sunlight to electrical energy.

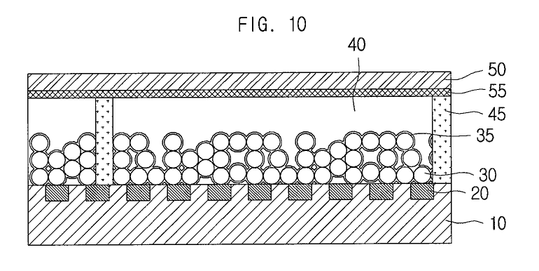

FIG. 10 is a cross-sectional view illustrating a dye-sensitized solar cell in accordance with another aspect of the present invention. Illustrated in FIG. 10 are the transparent polymer board 10, the metal transparent electrode 20, the electron transfer layer 30, the photosensitive dye 35, an electrolyte 40, a support 45, an upper electrode board 50 and a metal film 55.

As set for the above, the metal transparent electrode 20, in which nanometer-sized holes are formed, is formed on the transparent polymer board 10, and the photosensitive dye 35 is coupled to the electron transfer layer 30 formed on the metal transparent electrode 20. The lower electrode including the transparent polymer board 10, the metal transparent electrode 20 and the electron transfer layer 30, to which the photosensitive dye 35 is coupled, has been described earlier with reference to the method of manufacturing an electrode, and thus detailed description of the lower electrode will be omitted.

The upper electrode includes the upper electrode board 50 and the metal film 55 formed on one surface of the upper electrode board 50. Although there is no restriction on the material used for the upper electrode board 50, a material such as glass or a transparent polymer can be used to allow light to easily pass through, and a flexible material can be used to provide a flexible solar cell.

The upper electrode can be manufactured by forming the metal film 55 on one surface of the upper electrode board 50 by sputtering a metal, such as platinum, palladium, silver or gold, which is highly catalytic for increasing the rate of a chemical reaction. If the upper electrode board 50 is made of a conductive material, the board itself can function as an electrode, and an electro plating method can be used when forming the metal film 55.

The upper electrode and the lower electrode are stacked over each other by interposing the support 45 such that there is some space between them, as illustrated in FIG. 10. Then, the dye-sensitized solar cell is completed by injecting the electrolyte 40 into the dye-sensitized solar cell and sealing the dye-sensitized solar cell.

The operating process of the dye-sensitized solar cell illustrated in FIG. 10 shows that the dye molecule coupled to the electron transfer layer 30 generates electrons and holes when light is irradiated, and then the electron is injected into a electron transfer of the electron transfer layer 30 and transferred to the metal transparent electrode 20 along the surface between nanoparticles, generating electric current in the solar cell. The holes generated at the dye molecule can be deoxidized and filled again by receiving the electrons through an oxidation-reduction reaction with the electrolyte 40.

While the spirit of the invention has been described in detail with reference to particular embodiments, the embodiments are for illustrative purposes only and shall not limit the invention. It is to be appreciated that those skilled in the art can change or modify the embodiments without departing from the scope and spirit of the invention. As such, many embodiments other than those set forth above can be found in the appended claims.

What is claimed is:

1. A method of manufacturing an electrode of a dye-sensitized solar cell, the method comprising:
forming a metal transparent electrode on one surface of a transparent polymer board, the metal transparent electrode having holes formed therein;
forming a electron transfer layer on the metal transparent electrode; and
absorbing photosensitive dye into the electron transfer layer.

2. The method of claim 1, wherein the transparent polymer board is a flexible board.

3. The method of claim 1, wherein the transparent polymer board is made of a thermoplastic or photocurable material.

4. The method of claim 1, wherein the forming of the metal transparent electrode comprises:
forming an intaglio nano-pattern on one surface of the transparent polymer board; and
filling a conductive metal in the intaglio nano-pattern.

5. The method of claim 4, wherein the forming of the intaglio nano-pattern comprises:
preparing a stamp, in which a relievo nano-pattern corresponding to the intaglio nano-pattern is formed;
pressing and hardening the stamp by facing the surface of the stamp in which the relievo nano-pattern is formed against one surface of the transparent polymer board; and
exposing the intaglio nano-pattern by separating the stamp.

6. The method of claim 4, wherein the filling of the conductive metal is performed by way of sputtering.

7. The method of claim 1, wherein the holes are formed on the metal transparent electrode at regular intervals, the holes being smaller in size than the wavelength of visible light.

8. The method of claim 1, wherein the forming of the electron transfer layer comprises:
coating nano-crystal oxide on the metal transparent electrode; and
annealing the nano-crystal oxide.

9. The method of claim 8, wherein the nano-crystal oxide comprises TiO₂.

10. An electrode of a dye-sensitized solar cell, the electrode comprising:
a transparent polymer board;
a metal transparent electrode formed on one surface of the transparent polymer board, the metal transparent electrode having holes formed therein; and
a electron transfer layer formed on one surface of the transparent polymer board, the electron transfer layer having photosensitive dye absorbed therein.

11. The electrode of claim 10, wherein the transparent polymer board is a flexible board.

12. The electrode of claim 10, wherein the metal transparent electrode is buried in the transparent polymer board.

13. The electrode of claim 10, wherein the holes are formed on the metal transparent electrode at regular intervals, the holes being smaller than the wavelength of visible light in size.

14. The electrode of claim 10, wherein the electron transfer layer is made of a material comprising TiO₂.

15. A dye-sensitized solar cell comprising:
a lower electrode comprising a transparent polymer board and a electron transfer layer, a metal transparent electrode formed on one surface of the transparent polymer board, the metal transparent electrode having holes formed therein, the electron transfer layer being formed on one surface of the transparent polymer substance and having photosensitive dye absorbed therein;
an upper electrode comprising an upper electrode board and a metal film, the metal film formed on one surface of the upper electrode board; and
an electrolyte being interposed between the lower electrode and the upper electrode.

16. The dye-sensitized solar cell of claim 15, wherein the metal transparent electrode is buried in the transparent polymer board.

17. The dye-sensitized solar cell of claim 15, wherein the holes are formed on the metal transparent electrode at regular intervals, the holes being smaller than the wavelength of visible light in size.

18. The dye-sensitized solar cell of claim 15, wherein the electron transfer layer is made of a material comprising TiO₂.
